(19) United States
(12) Patent Application Publication
(10) Pub. No.: US 2007/0257364 A1
(43) Pub. Date: Nov. 8, 2007

(54) METHODS OF REACTIVE COMPOSITE JOINING WITH MINIMAL ESCAPE OF JOINING MATERIAL

(76) Inventors: David P. Van Heerden, Baltimore, MD (US); Timothy Ryan Rude, Baltimore, MD (US); Jesse E. Newson, Cockeysville, MD (US); Zhaojuan He, Columbia, MD (US); Etienne Besnoin, Baltimore, MD (US); Ramzi Vincent, Columbia, MD (US); Timothy P. Weihs, Baltimore, MD (US)

Correspondence Address: POLSTER, LIEDER, WOODRUFF & LUCCHESI, 12412 POWERSCOURT DRIVE SUITE 200, ST. LOUIS, MO, 63131-3615, US

(21) Appl. No.: 11/741,422

(22) Filed: Apr. 27, 2007

Related U.S. Application Data
(60) Provisional application No. 60/795,534, filed on Apr. 27, 2006.

(51) Int. Cl. H01L 23/48

(52) U.S. Cl. 257/737

(57) ABSTRACT

The present inventors have observed that in some applications of reactive composite joining there is escape of a portion of the molten joining material through the edges of the joining regions. Such escape is not only a waste of expensive material (e.g. gold or indium) but also a reduction from the optimal thickness of the joining regions. In some applications, such escape also presents risk of short circuits or even fire. In this invention, two approaches are taken toward preventing damage to surroundings by the escape of molten joining material. First, escape may be prevented by trapping or containing the molten material near the joint, using barriers, dams, or similar means. Second, escape may be reduced by adjusting parameters within the joint, such as solder composition, joining pressure, or RCM thickness.

### CROSS-REFERENCE TO RELATED APPLICATIONS

This application claims the benefit of U.S. Provisional Application Ser. No. 60/795,534 of same title filed Apr. 27, 2006 herein incorporated by reference.

### STATEMENT REGARDING FEDERALLY SPONSORED RESEARCH

The United States government has certain rights in this invention pursuant to NSF Award DMI-0349727 and NSF Award DMI-0321500.

### FIELD OF THE INVENTION

This invention relates to the joining of components with joining material such as solder or braze by reactive composite materials such as reactive multilayer foils. In particular, it relates to methods for such joining adapted for minimal escape of joining material from the joint.

### BACKGROUND OF THE INVENTION

Joining of components with joining materials melted by reactive composite materials is advantageous for many important applications. Many conventional methods of joining two components use a heat source external to the joint to melt or cure joining material disposed between the component surfaces to be joined. Such external heat sources are typically ovens or torches. They are relatively expensive and burdensome to transport. Moreover, external heating typically heats the components far from the joining region with the potential of damaging temperature sensitive components, e.g., integrated circuits, and causing stresses due to differential thermal contraction on cooling.

Reactive composite materials (RCMs) such as reactive multilayer foils can provide a source of portable, highly localized heat that melts or cures the joining material with minimal heating of component regions outside the joint. An RCM is typically composed of multiple alternating thin layers of materials that, upon ignition, will react with one another in an exothermic and self-propagating reaction. One advantageous RCM is comprised of many alternating nanoscale (<1 micrometer) thickness layers of nickel and aluminum. Further details concerning the structure and fabrication of RCMs may be found in U.S. Pat. No. 6,863,992 issued to T. Weihs et al. on Mar. 8, 2005, which is incorporated herein by reference.

FIG. 1, which is prior art, illustrates a typical method of forming a joint using an RCM. In the exemplary joint, one component 11 is covered with a layer of solder 12 pre-applied as by conventional reflow and then machined to the desired thickness, typically 100-500 μm. A sheet of RCM 13 is placed against this pre-wet solder layer, and a piece of sheet solder 14, typically 25-50 μm thick, is placed against the RCM. The joining surface of a second component 15, which is typically gold metallized, is pressed against the sheet solder; the assembly is placed under pressure 16; and the RCM is ignited, as symbolized by match 17. The RCM reacts, giving off heat, melting the solder sheet completely, partially melting the pre-wet solder, and ejecting some solder from the joint. When the solder remaining in the joint cools and re-solidifies, the two components are joined together. The present invention is directed to improvements in this process of joining components.

### SUMMARY OF THE INVENTION

The present inventors have observed that in some applications of reactive composite joining there is escape of a portion of the molten joining material through the edges of the joining regions. Such escape is not only a waste of expensive material (e.g. gold or indium) but also a reduction from the optimal thickness of the joining regions. In some applications, such escape also presents risk of short circuits or even fire. In this invention, two approaches are taken toward preventing damage to surroundings by the escape of molten joining material. First, escape may be prevented by trapping or containing the molten material near the joint, using barriers, dams, or similar means. Second, escape may be reduced by adjusting parameters within the joint, such as solder composition, joining pressure, or RCM thickness.

### BRIEF DESCRIPTION OF THE SEVERAL VIEWS OF THE DRAWINGS

The advantages, nature, and various additional features of the invention will appear more fully upon consideration of the illustrative embodiments now to be described in detail in connection with the accompanying drawings. In the drawings:

FIG. 1 illustrates reactive composite joining of components with joining materials melted by reactive composite materials;

FIG. 2 illustrates a window frame package assembly for containing molten joining material;

FIG. 3 illustrates a window frame of double-stick tape to contain molten joining material;

FIG. 4 illustrates a cut-away view of a joint surrounded by a space-filling barrier layer;

FIG. 5 illustrates a cut-away view of a joint surrounded by a thin barrier layer;

FIG. 6 illustrates a thick frame around an RCM sheet and a sheet of joining material;

FIG. 7 illustrates a conductive strip folded around the edges of an RCM sheet and a sheet of joining material;

FIG. 8 illustrates a joint wherein one component has an integral ridge to trap molten joining material;

FIG. 9 illustrates a joint wherein the RCM is smaller in area than the layers of joining material surrounding it;

FIG. 10 illustrates a layer of joining material with a non-melting mesh embedded in it; and

FIG. 11 illustrates a joint wherein the joining surfaces of the components are concave.

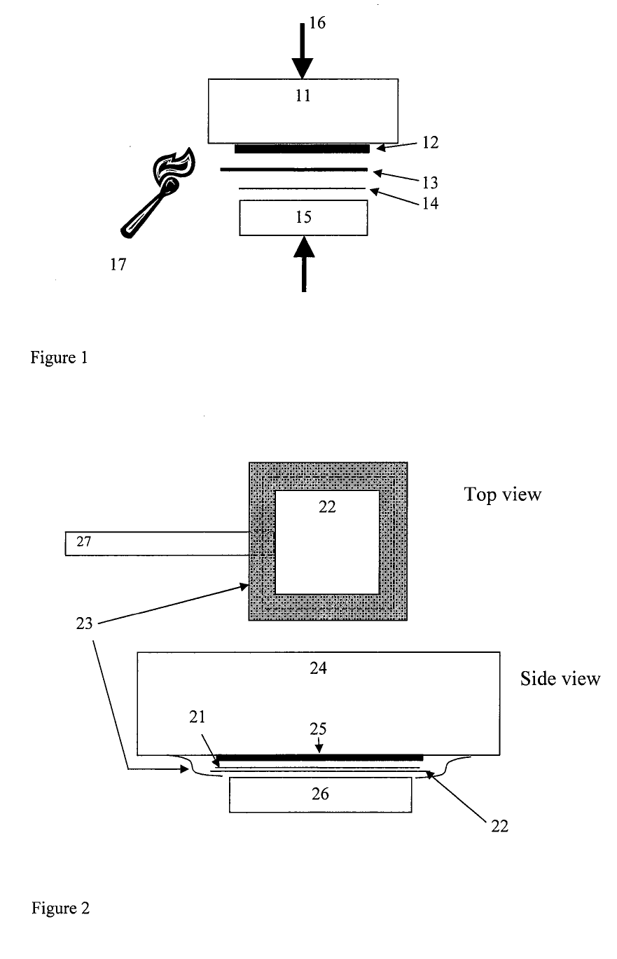

It is to be understood that these drawings are for purposes of illustrating the concepts of the invention and are not to scale.

### DETAILED DESCRIPTION OF THE PREFERRED EMBODIMENT

This discussion is divided into two parts: Part I describes reactive composite joining including steps for containing molten joining material and Part II is directed to joining with steps for reducing the amount of molten joining material. Depending on the specific application, an improved joining process can include one or more of these approaches.

I. Joining With Containment

Referring to the drawings, FIGS. 2 through 6 illustrate various ways of containing molten joining material in the reactive composite joining process.

In a first embodiment (FIG. 2), an RCM sheet 21 and a solder sheet 22 are adhered together, as by cladding or pressure. A window frame 23 of high-temperature resistant material with adhesive, such as Kapton® or aluminum tape, is placed against the solder sheet, extending beyond the sheet's edges, and adhered to component 24 and the pre-wet layer 25. The second component 26 fits within the window frame 23, thus pressing against the solder sheet 22. Ignition may be through the window frame 23 or via an electric lead or RCM lead 27 extending under the frame. The window frame 23 catches solder escaping from the pre-wet layer 25 and most of the solder escaping from solder sheet 22.

In variations on the first embodiment, the RCM piece 21 may be smaller than the second component 26, or the RCM 21 may extend under the window frame 23 for easier ignition. The RCM 21 may extend past the solder sheet 22 or be smaller than the solder sheet 22. The window frame 23 can be Kapton® or another polymer, or it can be metal, such as aluminum tape or copper tape. The frame 23 may provide protection from electrostatic discharge (ESD) before the packet is attached to component 24. The area of the pre-wet solder 25 on component 24 may be much larger than the area of the RCM 21.

For example, a gold-metallized piece of silicon wafer 26 (FIG. 2) with area approximately 1″×1″ was joined to a copper heat sink 24 with area approximately 3″×3″. The copper was pre-wet with indium solder 25 that was then machined back to a thickness of 150 μm. A sheet of indium (22) 25 μm thick and approximately 1.1″×1.1″ was pressed against a piece of RCM 21 approximately 1.1″×1.1″ in area, 60 μm thick with 40 nm bilayers (one Al layer+one Ni layer thickness) and 1 μm Incusil® on both surfaces. A window frame 23 of Kapton® tape 0.002″ (50 μm) thick was pressed against the indium solder sheet 22. The opening in the Kapton® tape 23 was just slightly larger than the silicon piece 26. A strip of RCM 27 was affixed to the window frame with one end against the RCM sheet 21. First, the copper heat sink 24 was placed on a flat surface. Next, the packet comprising window frame 23, solder sheet 22, RCM 21, and igniter 27 was affixed to the copper heat sink 24. The silicon piece 26 was placed against the solder sheet 22, inside the window frame 23. A spacer block was placed on the silicon piece and a round-end spring plunger was pressed against the spacer block to provide 50 PSI of pressure during joining. A small electric current was used to ignite the RCM igniter tab 27, which in turn ignited the joining foil 21. Some fraction of the solder melted, and upon resolidification, a joint was formed. Almost no spray was observed outside the window frame 23.

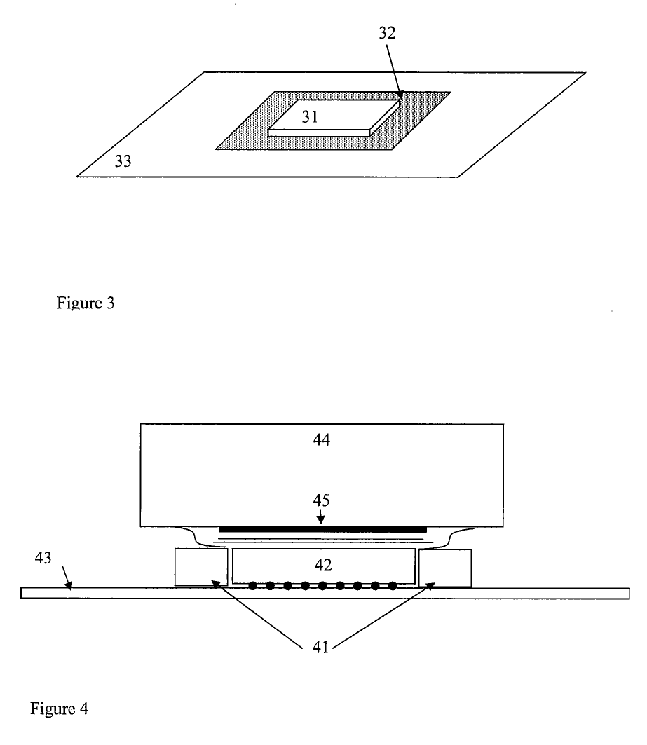

In a second embodiment (FIG. 3), the packet of the first embodiment is used in conjunction with a second window frame 32 of high-temperature tape, preferably Kapton®, with adhesive on both sides. In this case, component 31 can be a silicon chip or die attached to a circuit board 33. The window frame 32 is placed around the die 31, covering some area of the circuit board 33 nearest the die 31. The exposed adhesive on the window frame 32 traps any escaping molten solder while the tape 32 protects capacitors or other components located near the die 31. Advantageously, the window frame 32 may be left in place after joining.

In a variation on the second embodiment, solder wicking braid (usually tinned copper, used to remove solder during rework of a joint) may be affixed to the free surface of the double-sided tape. This braid will act as a dam and absorb escaping solder, containing it for easy removal. Alternately, the solder wicking braid may be placed around the joint without the aid of the tape to hold it in place, similar to the space-filling material described below.

In a third embodiment, shown in FIG. 4, a space-filling material 41 may be placed around component (die) 42 between a circuit board 43 and the other component (heat sink) 44. This material 41 serves to trap molten solder and to prevent its contact with the circuit board. The space-filling material may be foam, caulk, rubber, mesh, or any other compliant material that is compatible with the electronics on the board. Advantageously, the space-filling material may be left in place after joining. If the space-filling material 41 can be removed after joining, it may be reusable. If desired, the space-filling material 41 may be positioned some distance away from the joint, to avoid containing the escaped solder and any vapors right next to the joint. For example, a joint as shown in FIG. 2 was assembled, but an additional window frame of very compliant open-cell polyurethane foam was placed around component 42 (or 26). A spacer block larger than the area of the foam window frame 41 was placed above the silicon piece 42 (in place of the circuit board 43) to apply pressure to the joint and to the foam. The RCM was ignited and the joint formed. After joining, no solder was observed to have escaped the foam 41.

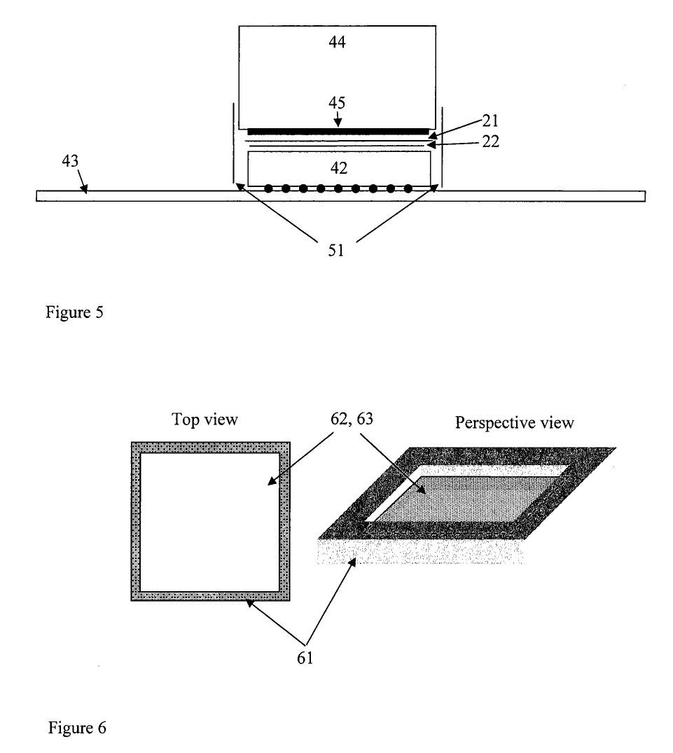

In a variation on this third embodiment (FIG. 5), the space-filling material may be a simple barrier 51, such as a polymer or metal tape, wrapped around the two components. It may be a reusable shield that is put in place for the joining event, then removed and reused. If the barrier is porous, such as a mesh, air and gases may escape without entraining molten solder, preventing solder escape and preventing pressure buildup inside the barrier.

In a fourth embodiment illustrated in FIG. 6, the RCM 63 and solder sheet 62 are attached to a thick frame 61 that may provide support to the foil and solder sheet during transport and handling. It can also provide ESD protection, and it can block solder escape. The frame 61 can be coplanar with the RCM 63 and solder sheet 62 on one face, or the RCM 63 and solder sheet 62 can be suspended within the frame 61, with the frame 61 extending above and below the surface of the RCM 63 and the solder sheet 62, as shown in FIG. 6. There may be a layer of solder sheet 62 on each side of the RCM 63, and the solder sheet or sheets can be clad to the RCM by cold or warm pressing or by other methods known in the art. The frame 61 advantageously resides outside the joining area. The embodiment may be implemented similarly to FIG. 4.

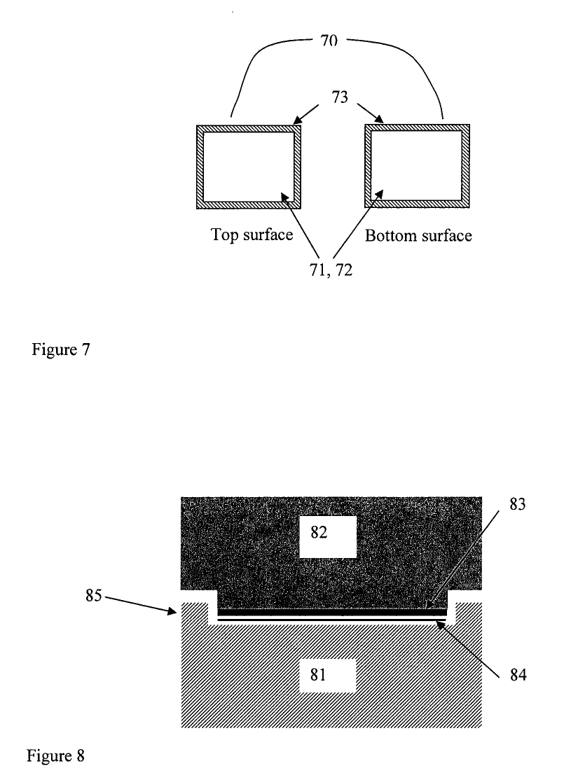

In a variation of this embodiment shown in FIG. 7, a thin conductive strip of metal foil 73 folded over the edges of the RCM 71 and solder sheet or sheets 72 may replace the thick frame of FIG. 6. The conductive strip permits electrical ignition through it. This embodiment may be combined with others: e.g. a conductive strip wrapped over a portion of an RCM-solder sheet package and an insulating tape frame covering the rest of the joint surroundings.

In another embodiment (FIG. 8), one of the parts may itself have a structure (e.g., a ridge 85) around the joining area to trap solder that might otherwise escape.

II. Joining With Reduction of Molten Material

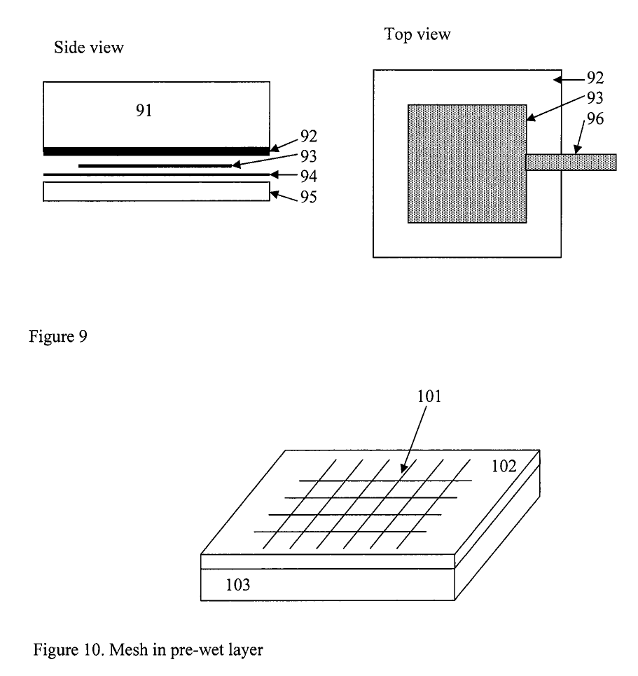

Various changes in the solder and RCM configuration may reduce solder escape. In one embodiment, reducing the area of the RCM compared to the bond region reduces solder escape. FIG. 9 illustrates this geometry. Component 91 is pre-wet with solder layer 92. Component 95 and solder sheet 94 are arranged as shown. The area of RCM 93 is smaller than the areas of pre-wet layer 92 and solder sheet 94. The joining surfaces of components 91 and 95 may be larger in area than solder layers 92 and 94. RCM 93 may be ignited with RCM tab 96, one end of which touches or overlaps RCM 93 while the other end extends past components 91 and 95 to permit ignition by a heat source. For example, a block of copper 91 (in FIG. 9) was pre-wet with indium solder 92 before bonding to silicon 95 with an aluminum-nickel RCM (93) 60 μm thick and a 25 μm thick sheet of indium solder 94. The RCM 93 was 10 mm×10 mm, which was smaller than the joint dimensions of 15 mm×15 mm. The RCM 93 was ignited with tab 96 to form a bond. Seven percent of the volume of the solder and RCM originally present in the bonding region was expelled during bonding. Compared to a joint wherein the RCM dimensions were 15 mm×15 mm, eighty-five percent (85%) less solder was lost.

In another embodiment, shown in FIG. 10, a wire mesh 101 is incorporated either between the RCM and solder sheet or within the solder sheet 102, to provide small barriers to solder loss and prevent complete compression of the joint. A convenient way to implement this is to include the mesh 101 in the pre-wet solder layer 102 on one component 103. For example, a block of copper 103 was pre-wet with indium solder 102. A thin Monel® mesh 101 was placed in the indium layer while it was still molten during the pre-wet process. The copper block was then bonded to silicon with an aluminum-nickel RCM 60 μm thick and a 25 μm thick sheet of indium solder. Five percent of the volume of the solder and RCM originally present in the bonding region was expelled during bonding. Compared to a joint without the Monel® mesh, eighty-one percent (81%) less solder was lost. In a variation on this embodiment, a wire spiral or short lengths of wire would also prevent complete compression of the joint but would still allow the solder to flow within the joint.

In another embodiment, a high-viscosity solder is used in the bond, reducing escape due to the solder's resistance to pressure. Off-eutectic solders exhibit a so-called “mushy zone” upon heating: they do not melt completely at one fixed temperature. If the temperature of the solder can be raised into the mushy zone but not beyond, the solder will be viscous and resist spray. Similarly, a two-component solder in which the two components are not thoroughly mixed but are layered in the solder sheet can impede melting and increase viscosity.

In another embodiment, a solder with a high melting point is pre-wet to the first component and a low-melting point solder sheet is placed against the second component. During joining the pre-wet layer will melt only partially, reducing escape, while the solder sheet will still melt completely to permit wetting of the second component.

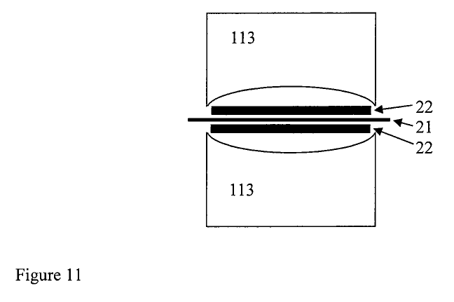

In another embodiment, the geometry of the joint is chosen to reduce solder escape. If one or both joining surfaces were concave, as shown in FIG. 11, solder would tend to flow toward the center rather than the edges of the joint.

In another embodiment, the volume or thickness of the RCM is reduced to provide the minimum heat required to bond the surfaces. Excessive heat can cause excessive solder flow and escape.

It is to be understood that the above-described embodiments are illustrative of only a few of the many embodiments that can represent applications of the invention. Numerous and varied other arrangements can be devised by those skilled in the art without departing from the spirit and scope of the invention.

What is claimed is:

1. A method of bonding a first component body to at least one additional component body, comprising the steps of:
disposing at least one sheet or layer of reactive composite material and
at least one sheet or layer of solder or braze between the component bodies;
disposing a non-reactive barrier around the perimeter of the sheet or layer of solder or braze;
applying pressure on the reactive composite material through the component bodies; and
initiating an exothermic reaction in the reactive composite material to form a bond between the first component body and the additional component body.

2. The method of claim 1 wherein the barrier comprises a polymer.

3. The method of claim 1 wherein the barrier comprises a metal foil.

4. The method of claim 1 wherein the barrier comprises an adhered material.

5. The method of claim 4 wherein the adhered material has exposed adhesive.

6. The method of claim 1 wherein the barrier comprises a space-filling material.

7. The method of claim 1 wherein the barrier comprises open-celled foam.

8. The method of claim 1 wherein the barrier comprises an extruded material.

9. The method of claim 1 wherein the barrier comprises a caulk.

10. The method of claim 1 wherein the barrier comprises closed-cell foam.

11. The method of claim 1 wherein the barrier comprises an elastomer.

12. The method of claim 1 wherein the barrier is affixed to the reactive composite material.

13. The method of claim 1 wherein the barrier is affixed to the solder or braze.

14. The method of claim 1 wherein the barrier is affixed to at least one of the two components.

15. The method of claim 1 wherein the barrier is affixed to more than one of the two components.

16. The method of claim 1 wherein the barrier is part of one of the component bodies.

17. A joint made by the method of claim 1.

18. A joint having a joining region surrounded by a barrier of non-reactive material.

19. The joint of claim 16 wherein the barrier comprises a polymer.

20. The joint of claim 16 wherein the barrier comprises a metal foil.

21. The joint of claim 16 wherein the barrier comprises an adhered material.

22. The joint of claim 19 wherein the adhered material has exposed adhesive.

23. The joint of claim 16 wherein the barrier comprises a space-filling material.

24. The joint of claim 16 wherein the barrier comprises open-celled foam.

25. The joint of claim 16 wherein the barrier comprises an extruded material.

26. The joint of claim 16 wherein the barrier comprises a caulk.

27. The joint of claim 16 wherein the barrier comprises closed-cell foam.

28. The joint of claim 16 wherein the barrier comprises an elastomer.

29. The joint of claim 16 wherein the barrier is affixed to the reactive composite material.

30. The joint of claim 16 wherein the barrier is affixed to the solder or braze.

31. The joint of claim 16 wherein the barrier is affixed to at least one of the two components.

32. The joint of claim 16 wherein the barrier is affixed to more than one of the two components.

33. The joint of claim 16 wherein the barrier is part of one of the component bodies.

34. A method of bonding a first component body to at least one additional component body, comprising the steps of:
disposing at least one sheet or layer of reactive composite material and
at least one sheet or layer of solder or braze between the component bodies;
applying pressure on the reactive composite material through the component bodies; and
initiating an exothermic reaction in the reactive composite material to form a bond between the first component body and the additional component body,
wherein the volume of material expelled from the region between the bodies is less than 25% of the sum of the volumes of the solder or braze and reactive composite material.

35. A method of bonding a first component body to at least one additional component body, comprising the steps of:
disposing at least one sheet or layer of reactive composite material and
at least one sheet or layer of solder or braze between the component bodies;
applying pressure on the reactive composite material through the component bodies; and
initiating an exothermic reaction in the reactive composite material to form a joining region between the first component body and the additional component body,
wherein the area of the reactive composite material is smaller than the area of the joining region.

36. An object comprising:
at least a first component with at least one joining surface coated with a layer of solder or braze alloy;
reaction remnants of a reactive composite material adhered to the layer of solder or braze alloy on the joining surface of the first component; and
at least a second component with at least one joining surface adhered to the remnants of the reactive composite material,
wherein the reaction remnants of the reactive composite material are smaller in area than the joining surfaces.

37. A method of bonding a first component body to at least one additional component body, comprising the steps of:
disposing at least one sheet or layer of reactive composite material and
at least one sheet or layer of solder or braze between the component bodies;
applying pressure on the reactive composite material through the component bodies; and
initiating an exothermic reaction in the reactive composite material to form a bond between the first component body and the additional component body,
wherein the solder or braze comprises a material that does not melt during the exothermic reaction.

38. An object comprising:
at least a first component with at least one joining surface coated with a layer comprising solder or braze alloy wherein the layer further comprises a material with substantially higher melting point than that of the solder or braze;
reaction remnants of a reactive composite material adhered to the solder or braze alloy on the joining surface of the first component; and
at least a second component with at least one joining surface adhered to the remnants of the reactive composite material.

39. The object of claim 36 wherein the material with a substantially higher melting point than that of the solder or braze comprises a mesh.

40. The object of claim 36 wherein the material with substantially higher melting point than that of the solder or braze comprises a spiral.

41. The object of claim 36 wherein the material with substantially higher melting point than that of the solder or braze comprises short lengths of wire.

42. An object comprising:
at least a first component with at least one joining surface coated with a layer of a solder or braze alloy;
reaction remnants of a reactive composite material adhered to the solder or braze alloy; and
at least a second component with at least one joining surface adhered to the remnants of the reactive composite material,
wherein at least one of the joining surfaces is concave.
